(19) United States
(12) Patent Application Publication
(10) Pub. No.: US 2008/0299733 A1
(43) Pub. Date: Dec. 4, 2008

(54) METHOD OF FORMING A SEMICONDUCTOR STRUCTURE COMPRISING AN IMPLANTATION OF IONS IN A MATERIAL LAYER TO BE ETCHED

(76) Inventors: Patrick Press, Dresden (DE); Frank Wirbeleit, Dresden (DE); Joe Bloomquist, Austin, TX (US); Kai Frohberg, Niederau (DE); Thomas Feudel, Radebeul (DE)

Correspondence Address: WILLIAMS, MORGAN & AMERSON, 10333 RICHMOND, SUITE 1100, HOUSTON, TX, 77042, US

(21) Appl. No.: 11/969,412

(22) Filed: Jan. 4, 2008

(30) Foreign Application Priority Data
May 31, 2007 (DE) 10 2007 025 326.7

(51) Int. Cl. H01L 21/336

(52) U.S. Cl. 438/299; 257/E21.409

(57) ABSTRACT

A method of forming a semiconductor structure comprises providing a semiconductor substrate. A feature having a side surface and a top surface is formed over the substrate. A material layer is formed over the substrate. The material layer covers at least the side surface of the feature. An ion implantation process is performed to create an ion-implanted portion in the material layer. An etch process adapted to remove the ion-implanted portion at a greater etch rate than other portions of the material layer is performed.

### BACKGROUND OF THE INVENTION

1. Field of the Invention

The present disclosure generally relates to the fabrication of integrated circuits, and, more specifically, to methods of forming a semiconductor structure wherein ions are implanted into a material layer to modify an etch rate of the material layer in an etching process.

2. Description of the Related Art

Integrated circuits comprise a large number of individual circuit elements, e.g., transistors, capacitors and resistors. These elements are connected internally to form complex circuits such as memory devices, logic devices and microprocessors. The performance of integrated circuits may be improved by increasing the number of functional elements per circuit in order to increase their functionality and/or by increasing the speed of operation of the circuit elements. A reduction of feature sizes allows the formation of a greater number of circuit elements on the same area, hence allowing an extension of the functionality of the circuit, and also reduces signal propagation delays, thus making an increase of the speed of operation of circuit elements possible.

Field effect transistors are used as switching elements in integrated circuits. They provide a means to control a current flowing through a channel region located between a source region and a drain region. The source region and the drain region are highly doped. In N-type transistors, the source and drain regions are doped with an N-type dopant. Conversely, in P-type transistors, the source and drain regions are doped with a P-type dopant. The doping of the channel region is inverse to the doping of the source region and the drain region. The conductivity of the channel region is controlled by a gate voltage applied to a gate electrode formed above the channel region and separated therefrom by a thin insulating layer. Depending on the gate voltage, the channel region may be switched between a conductive “on” state and a substantially non-conductive “off” state.

When reducing the size of field effect transistors, it is important to maintain a high conductivity of the channel region in the “on” state. The conductivity of the channel region in the “on” state depends on the dopant concentration in the channel region, the mobility of the charge carriers, the extension of the channel region in the width direction of the transistor and on the distance between the source region and the drain region, which is commonly denoted as “channel length.” While a reduction of the width of the channel region leads to a decrease of the channel conductivity, a reduction of the channel length enhances the channel conductivity. An increase of the charge carrier mobility leads to an increase of the channel conductivity.

As feature sizes are reduced, the extension of the channel region in the width direction is also reduced. A reduction of the channel length entails a plurality of issues associated therewith. First, advanced techniques of photolithography and etching have to be provided in order to reliably and reproducibly create transistors having short channel lengths. Moreover, highly sophisticated dopant profiles, in the vertical direction as well as in the lateral direction, are required in the source region and in the drain region in order to provide a low sheet resistivity and a low contact resistivity in combination with a desired channel controllability.

In view of the problems associated with a further reduction of the channel length, it has been proposed to also enhance the performance of field effect transistors by increasing the charge carrier mobility in the channel region. In principle, at least two approaches may be used to increase the charge carrier mobility.

First, the dopant concentration in the channel region may be reduced. Thus, the probability of scattering events of charge carriers in the channel region is reduced, which leads to an increase of the conductivity of the channel region. Reducing the dopant concentration in the channel region, however, significantly affects the threshold voltage of the transistor device. This makes the reduction of dopant concentration a less attractive approach.

Second, the lattice structure in the channel region may be modified by creating tensile or compressive stress. This leads to a modified mobility of electrons and holes, respectively. Depending on the magnitude of the stress, a compressive stress may significantly increase the mobility of holes in a silicon layer. The mobility of electrons may be increased by providing a silicon layer having a tensile stress.

A method of forming a semiconductor structure comprising field effect transistors wherein the channel region is formed in stressed silicon will be described in the following with reference to FIGS. 1a-1d.

FIG. 1a shows a schematic cross-sectional view of a semiconductor structure 100 in a first stage of a manufacturing process according to the state of the art. The semiconductor structure 100 comprises a substrate 101. In the substrate 101, a first active region 104 and a second active region 204 are provided. A trench isolation structure 102 electrically insulates the active regions 104, 204 from each other and from other elements of the semiconductor structure 100 which are not shown in FIG. 1a.

A gate electrode 106 which is separated from the substrate 101 by a gate insulation layer 105 is formed over the first active region 104. The gate electrode 106 is covered by a cap layer 107 and flanked by a sidewall spacer structure 108. The active region 104, the trench isolation structure 102, the gate electrode 106, the gate insulation layer 105, as well as the first sidewall spacers 108, 109 and the cap layer 107 together form portions of a first field effect transistor element 130.

The semiconductor structure 100 further comprises a second transistor element 230. Similar to the first transistor element 130, the second transistor element 230 comprises a gate electrode 206, a gate insulation layer 205 and a sidewall spacer structure 208. A cap layer 207 covers the gate electrode 206.

In the formation of the semiconductor structure 100, the substrate 101 is provided and the trench isolation structure 102 is formed by means of methods of photolithography, deposition and/or oxidation known to persons skilled in the art. Then, ions of a dopant material are implanted into the substrate 101 in order to form the active regions 104, 204. The type of dopant corresponds to the doping of the channel regions of the transistor elements 130, 230 to be formed. Hence, if the first transistor element 130 and the second transistor element 230 are N-type transistors, ions of a P-type dopant are implanted, and ions of an N-type dopant may be implanted if the first transistor element 130 and the second transistor element 230 are P-type transistors. In other examples of manufacturing methods according to the state of the art, the first transistor element 130 and the second transistor element 230 may be transistors of a different type. In such examples, one of the first transistor element 130 and the second transistor element 230 may be covered by a mask which may, for example, comprise a photoresist, while ions are implanted into the other transistor element 130, 230.

After the formation of the active regions 104, 204, an oxidation process is performed to form the gate insulation layers 105, 205. Thereafter, the gate electrodes 106, 206 and the cap layers 107, 207 are formed by deposition, etching and photolithography processes that are well known to persons skilled in the art. Subsequently, the sidewall spacer structures 108, 208 are formed by depositing a layer of a spacer material and performing an anisotropic etch process wherein portions of the layer of spacer material over substantially horizontal portions of the semiconductor structure 100 are removed, whereas portions of the layer of spacer material provided on the sidewalls of the gate electrodes 106, 206 remain on the substrate 101 and form the sidewall spacer structures 108, 208.

A schematic cross-sectional view of the semiconductor structure 100 in a later stage of the manufacturing process according to the state of the art is shown in FIG. 1b. An etch process is performed. The etch process can be an isotropic etch process adapted to selectively remove the material of the substrate 101, leaving the material of the cap layers 107, 207 and the sidewall spacer structures 108, 208 substantially intact, for example, a known dry etch process. The cap layer 107 and the sidewall spacer structures 108, 208 protect the gate electrodes 106, 206, the gate insulation layers 105, 205 and channel regions of the transistor elements 130, 230 below the gate electrodes 106, 206 from being affected by an etchant used in the etch process.

Portions of the substrate 101 adjacent the gate electrodes 106, 206, however, are etched away. Thus, a source side cavity 110 and a drain side cavity 111 are formed adjacent the gate electrode 106 of the first transistor element 130. Similarly, adjacent the gate electrode 206 of the second transistor element 230, a source side cavity 210 and a drain side cavity 211 are formed. Due to the isotropy of the etch process, portions of the substrate 101 below the sidewall spacer structures 108, 208 and, optionally, also portions of the substrate 101 below the gate electrodes 106, 206 are removed. Therefore, the cavities 110, 111 may extend below the sidewall spacer structures 108, 208 and/or the gate electrodes 106, 206.

Subsequently, stress-creating elements 114, 115 are formed adjacent the gate electrode 106 of the first transistor element 130, and stress-creating elements 214, 215 may be formed adjacent the gate electrode 206 of the second transistor element 230. To this end, the cavities 110, 111, 210, 211 are filled with a layer of a stress-creating material. In methods of forming a field effect transistor according to the state of the art, the stress-creating material may comprise silicon germanide. As persons skilled in the art know, silicon germanide is an alloy of silicon (Si) and germanium (Ge). Other materials may be employed as well.

Silicon germanide is a semiconductor material having a greater lattice constant than silicon. When silicon germanide is deposited in the cavities 110, 111, 210, 211, however, the silicon and germanium atoms in the stress-creating elements 114, 115, 214, 215 tend to adapt to the lattice constant of the silicon in the substrate 101. Therefore, the lattice constant of the silicon germanide in the stress-creating elements 114, 115, 214, 215 is smaller than the lattice constant of a bulk silicon germanide crystal. Thus, the material of the stress-creating elements 114, 115, 214, 215 is compressively stressed.

The stress-creating elements 114, 115, 214, 215 may be formed by means of selective epitaxial growth. As persons skilled in the art know, selective epitaxial growth is a variant of plasma enhanced chemical vapor deposition wherein parameters of the deposition process are adapted such that material is deposited only on the surface of the substrate 101 in the cavities 110, 111, whereas substantially no material deposition occurs on the surface of the sidewall spacer structures 108, 208 and the cap layers 107, 207.

Since the stress-creating elements 114, 115, 214, 215 are compressively stressed, they exhibit a force to portions of the substrate 101 in the vicinity of the gate electrodes 106, 206, in particular to portions of the substrate 101 below the gate electrodes 106, 206 wherein channel regions of the transistor elements 130, 230 are to be formed. Therefore, a compressive stress is created below the gate electrodes 130, 230.

FIG. 1c shows a schematic cross-sectional view of the semiconductor structure 100 in yet another stage of the manufacturing process according to the state of the art. After the formation of the stress-creating elements 114, 115, 214, 215, the sidewall spacer structures 108, 208 are removed. Additionally, the cap layers 107, 207 may be removed. Thereafter, an extended source region 116 and an extended drain region 117 are formed in portions of the substrate 101 and the stress-creating elements 114, 115 adjacent the gate electrode 106 of the first transistor element 130 by means of an ion implantation process known to persons skilled in the art. Additionally, in the ion implantation process, an extended source region 216 and an extended drain region 217 may be formed adjacent the gate electrode 206 of the second transistor element 230. In the ion implantation process, ions of a dopant material are introduced into the substrate 101 and the stress-creating elements 114, 115, 214, 215. In case of the formation of N-type field effect transistors, ions of an N-type dopant are introduced, whereas ions of a P-type dopant are provided in the formation of P-type transistors. If the first transistor element 130 and the second transistor element 230 are transistors of a different type, two sequential ion implantation processes may be performed to introduce dopant ions of different type into the first transistor element 130 and the second transistor element 230. In each of the ion implantation processes, one of the first transistor element 130 and the second transistor element 230 may be covered by a mask absorbing ions and thus protecting the respective transistor element 130, 230 from being irradiated with ions. The mask may, for example, comprise a photoresist.

Subsequently, second sidewall spacer structures 108, 208 may be formed adjacent the gate electrodes 106. Thereafter, one or more further ion implantation processes may be performed to form source regions 120, 220 and drain regions 121, 221 in the first transistor element 130 and the second transistor element 230 by introducing dopant material ions.

Thereafter, an annealing process may be performed to activate the dopant materials introduced in the formation of the extended source regions 116, 216, the extended drain regions 117, 217, the source regions 120, 220 and the drain regions 121, 221.

After the annealing process, a layer 160 of a dielectric material may be formed over the semiconductor structure 100. The layer 160 may, for example, comprise silicon nitride, and may be formed by means of deposition techniques well known to persons skilled in the art such as chemical vapor deposition and/or plasma enhanced chemical vapor deposition. Parameters of the deposition process may be adapted such that the layer 160 is subject to a compressive stress. In other examples, the layer 160 may be subject to a tensile stress. Thus, the stress exerted by the stress-creating regions 114, 115, 214, 215 to portions of the substrate 101 below the gate electrodes 106, 206 may be modified. While a compressive intrinsic stress of the layer 160 may enhance the stress in the substrate portions, a tensile intrinsic stress of the layer 160 may reduce the stress in the substrate portions.

In modern semiconductor structures 100, in particular in semiconductor structures wherein minimum feature sizes have an extension of about 65 nm or less, the distance between the first transistor element 130 and the second transistor element 230, in particular the distance between the gate electrodes 106, 206, may be relatively small. Thus, the space between the gate electrodes 106, 206 may have a shape of a relatively narrow groove. In the formation of the cavities 110, 111, 210, 211, the trench isolation structure 102 may be affected to some extent by the etchant used. Thus, the depth of the space between the gate electrodes 106, 206 may be further increased.

In the formation of the layer 160 of dielectric material, the shape of the space between the gate electrodes 106, 206 may hinder a reactant gas used in the chemical vapor deposition process or plasma enhanced chemical vapor deposition process from entering the space. This may lead to the formation of a void 161 in the layer 160.

FIG. 1d shows a schematic cross-sectional view of the semiconductor structure 100 in a later stage of the manufacturing process according to the state of the art. After the formation of the layer 160 of dielectric material, a layer 162 comprising an interlayer dielectric may be deposited over the semiconductor structure 100. In some examples of manufacturing methods according to the state of the art, the layer 162 may be planarized by means of a known chemical mechanical polishing process to obtain a substantially planar surface of the layer 162.

Thereafter, contact vias 162, 163, 164 may be formed over the source region 120, the gate electrode 106 and the drain region 121, respectively, of the first transistor element 130. Additionally, contact vias 262, 263, 264 may be formed over the source region 220, the gate electrode 206 and the drain region 215 of the second transistor element 230. Then, the contact vias 162, 163, 164, 262, 263, 264 may be filled with an electrically conductive material, for example a metal such as tungsten, to provide electrical connections to the source, drain and gate of the first transistor element 130 and the second transistor element 230, respectively. The formation of the contact vias 162, 163, 164, 262, 263, 264 and the filling of the contact vias 162, 163, 164, 262, 263, 264 with the electrically conductive material may be performed by means of processes of photolithography, etching, deposition and chemical mechanical polishing well known to persons skilled in the art.

A problem of the above-described manufacturing method according to the state of the art is that the cavity 161 may be filled with the electrically conductive material when the contact vias 162, 163, 164, 262, 263, 264 are filled with the electrically conductive material. The electrically conductive material 261 may provide undesirable electrical connections between the first transistor element 130 and the second transistor element 230, or between one of the first transistor element 130 and the second transistor element 230 and further transistor elements (not shown) in the semiconductor structure 100 which may adversely affect the functionality of the semiconductor structure 100.

A further problem of the above-described manufacturing method according to the state of the art is that a thickness of the second sidewall spacer structures 118, 218 may be influenced by varying properties of processes of deposition and/or etching used in the formation of the second sidewall spacer structures 118, 218. Thus, distances between the source regions 120, 220 and the gate electrodes 106, 206, and distances between the drain regions 121, 221 and the gate electrodes 106, 206 may vary. This may introduce undesirable variations of the electrical properties of the transistor elements 130, 230 between different semiconductor structures 100.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to an illustrative example, a method of forming a semiconductor structure comprises providing a semiconductor substrate. A feature having a side surface and a top surface is formed over the substrate. A material layer is formed over the substrate. The material layer covers at least the side surface of the feature. An ion implantation process is performed to create an ion-implanted portion in the material layer. An etch process adapted to remove the ion-implanted portion at a greater etch rate than other portions of the material layer is performed.

According to another illustrative example, a method of forming a semiconductor structure comprises providing a semiconductor substrate. A gate electrode is formed over the substrate. The gate electrode has a top surface and a side surface. A material layer is deposited over the top surface and the side surface. An ion implantation process is performed to create an ion-implanted portion in the material layer over the top surface of the gate electrode. An etch process adapted to remove the ion-implanted portion at a greater etch rate than other portions of the material layer is performed. The etch process is stopped upon removal of a portion of the material layer over the top surface such that portions of the material layer over the side surface form a sidewall spacer structure adjacent the gate electrode.

According to a further illustrative example, a method of forming a semiconductor structure comprises providing a semiconductor substrate comprising a gate electrode and a sidewall spacer structure formed adjacent the gate electrode. An ion implantation process is performed to form an ion-implanted portion in the sidewall spacer structure. An etch process adapted to remove the ion-implanted portion at a greater etch rate than other portions of the sidewall spacer structure is performed. The etch process is stopped prior to complete removal of the sidewall spacer structure.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d show schematic cross-sectional views of a semiconductor structure in stages of a method of manufacturing a semiconductor structure according to the state of the art; and

FIGS. 2a-2d show schematic cross-sectional views of a semiconductor structure in stages of a method of manufacturing a semiconductor structure according to an illustrative embodiment disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

According to one embodiment, an ion implantation is performed to create an ion-implanted portion in a material layer covering a feature formed on a surface of a substrate. The feature may, in some embodiments, comprise a gate electrode of a transistor element, and the material layer may comprise a spacer material such as, for example, silicon dioxide, silicon nitride and/or silicon oxynitride. In some embodiments, the ion implantation may be performed before an anisotropic etch process used to remove portions of the material layer from a top surface of the feature and the surface of the substrate. In other embodiments, the ions may be implanted into a sidewall spacer structure comprising the material layer. The implantation of ions may modify a structure of the material in the ion-implanted portion. Due to this modification, an etch rate of the ion-implanted portion in a second etch process performed after the ion implantation may differ from an etch rate of other portions of the material layer. In the second etch process, a shape of the material layer may be altered, wherein the shape obtained after the etch process may depend on the location of the ion-implanted portion.

In the ion implantation process, a direction of incidence of the ions in the ion implantation process may be substantially perpendicular to a surface of the substrate. Hence, a relatively high dose of ions may be implanted into portions of the material layer being substantially horizontal or including only a relatively small angle with the surface of the substrate, whereas a lower dose of ions or substantially no ions at all may be implanted into portions of the material layer including a relatively large angle with the substrate surface or being substantially perpendicular to the substrate surface. Hence, the ion-implanted portion may be selectively formed in portions of the material layer being substantially horizontal or relatively weakly inclined.

Thus, in embodiments wherein the material layer is covering a top surface and a side surface, the ion-implanted portion may be formed in portions of the material layer over the top surface. In embodiments wherein the material layer comprises a sidewall spacer structure formed adjacent the feature and covering the side surface of the feature, the ion-implanted portion may be formed in portions of the sidewall spacer structure in the vicinity of the top of the sidewall spacer structure.

As already mentioned above, after the ion implantation process, an etch process may be performed, wherein an etch rate of the ion-implanted portion may be different than an etch rate of other portions of the material layer. In particular, the etch rate of the ion-implanted portion may be greater than the etch rate of the other portions.

In embodiments wherein the material layer is covering the top surface and the side surface of the feature, the etch process may be anisotropic, and may be performed to form a sidewall spacer structure from the material layer. As persons skilled in the art know, in anisotropic etching, an etch rate of substantially horizontal or weakly inclined portions of the material layer may be greater than an etch rate of relatively steep portions of the material layer. Therefore, the increased etch rate of the ion-implanted portion provided in substantially horizontal or weakly inclined portions of the material layer may help to increase the degree of anisotropy of the etch process. Therefore, an amount of material removed over the side surface of the substrate, if the etch process is performed until portions of the material layer over the top surface of the feature and the substrate are completely removed, may be reduced. This may help reduce variations of the thickness of the sidewall spacer structure introduced by varying properties of the etch process. Hence, the thickness of the sidewall spacer structure may be advantageously controlled more precisely. Moreover, a relatively steep profile of the sidewall spacer structure may be obtained, which may be desirable in some applications.

In embodiments wherein the material layer comprises a sidewall spacer structure, in the etch process, relatively weakly inclined portions of the sidewall spacer structure in the vicinity of the top of the sidewall spacer structure may be removed at a greater etch rate than relatively steep portions in the vicinity of the bottom of the sidewall spacer structure. Therefore, the shape of the sidewall spacer structure may be modified to obtain a more tapered profile of the sidewall spacer structure. In embodiments wherein the feature comprises a gate electrode of a transistor element, and a gate electrode of another transistor element is provided in the vicinity thereof, a space between the gate electrodes may have sloped sidewalls. When a layer of a dielectric material, which may, in some embodiments, comprise a tensile or compressive stress, is deposited over the semiconductor structure, the sloped sidewalls may improve the deposition of material between the gate electrodes. This may help avoid formation of voids and electric shortcuts which may be created when electrical connections to the transistor elements are formed.

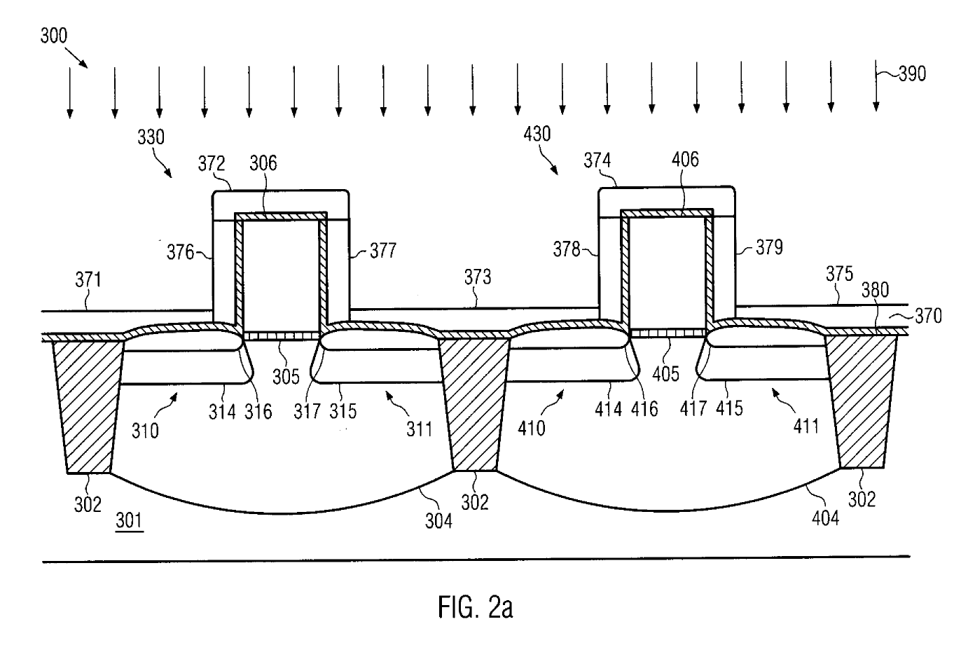

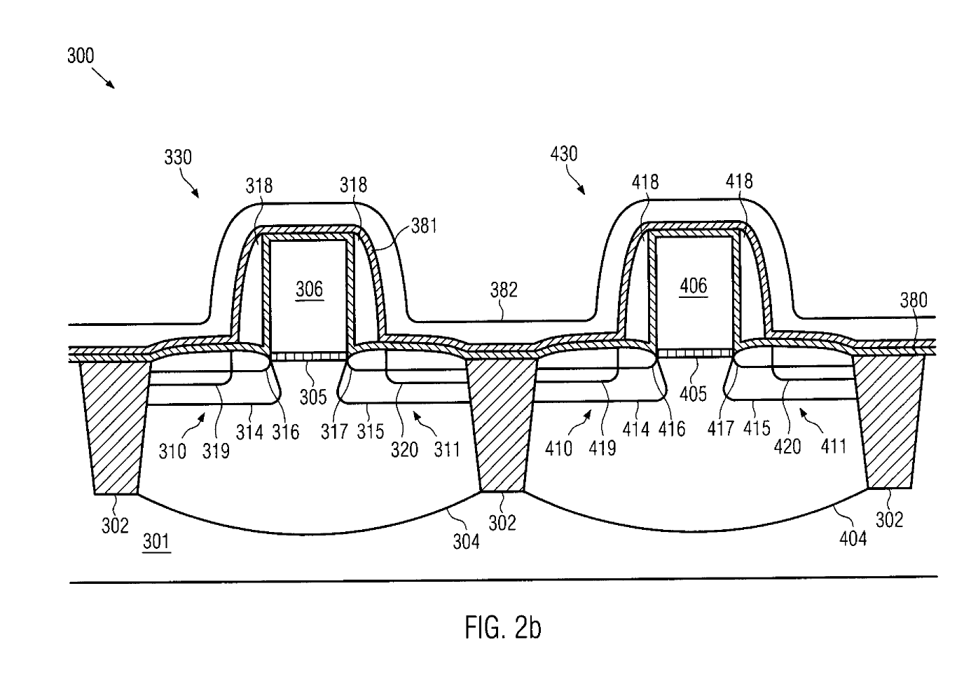

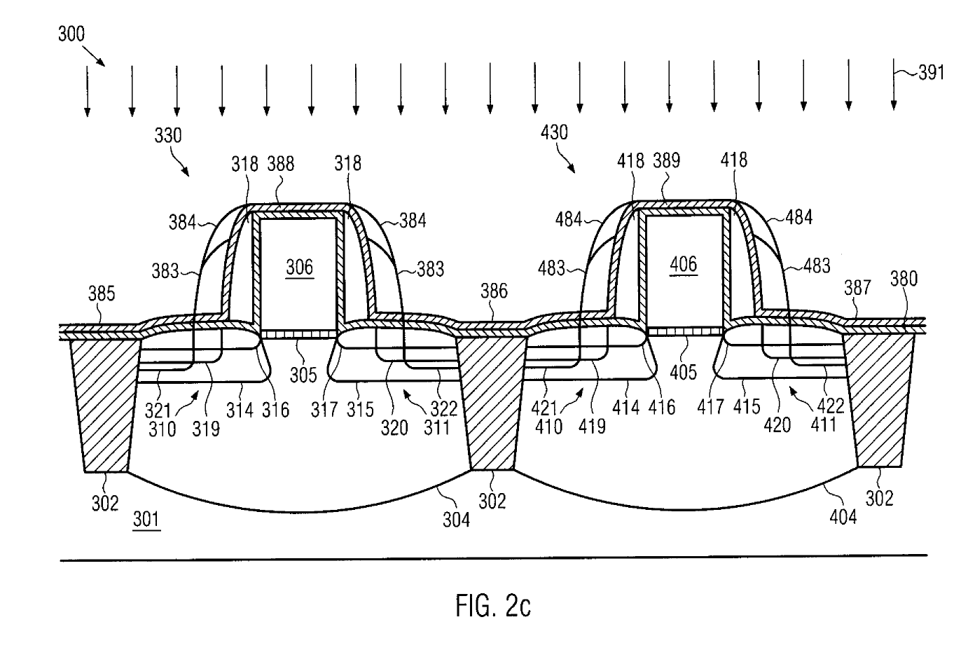

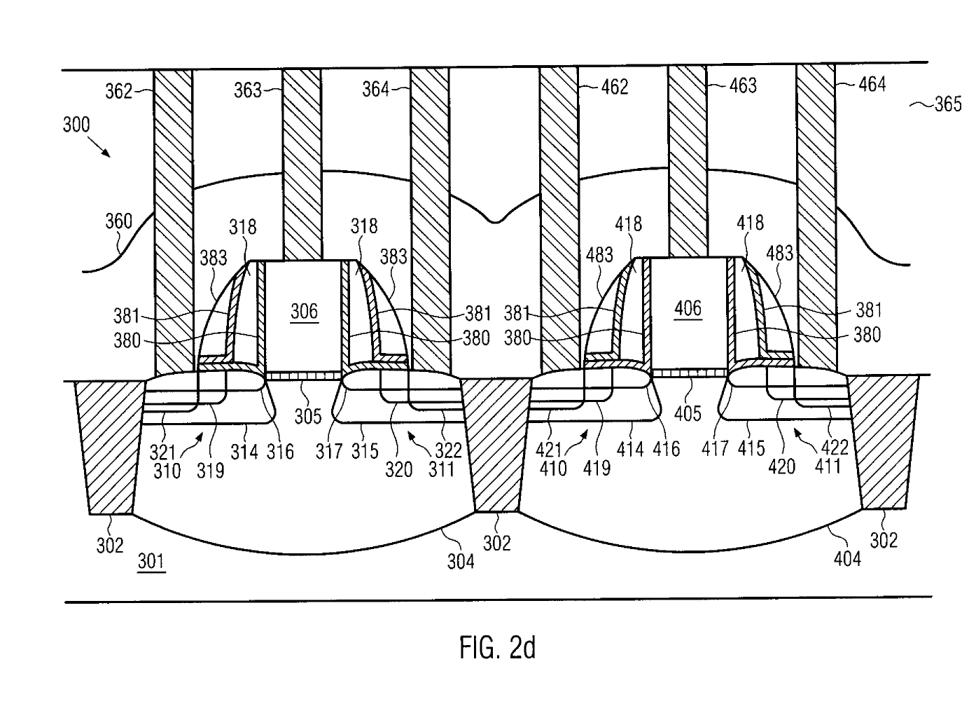

FIG. 2a shows a schematic cross-sectional view of a semiconductor structure 300 in a first stage of a method of manufacturing a semiconductor structure. The semiconductor structure 300 comprises a semiconductor substrate 301 which may, in some embodiments, comprise a silicon wafer. In some embodiments, the substrate 301 may comprise a silicon-on-insulator (SOI) substrate comprising a layer of silicon formed over a layer of an insulating material such as silicon dioxide. The semiconductor structure 300 comprises a first transistor element 330 and a second transistor element 430. In the substrate 301, a trench isolation structure 302, providing electrical insulation between the first transistor element 330 and the second transistor element 430, is formed. The first transistor element 330 comprises an active region 304 formed in the substrate 301. The active region 304 comprises a dopant of a type opposite to that of the transistor type of the first transistor element 330. Hence, if the first transistor element 330 is an N-type transistor, the active region 304 may comprise a P-type dopant. Conversely, if the first transistor element 330 is a P-type transistor, the active region 304 may comprise an N-type dopant.

A gate electrode 306 is formed over the active region 304 and is separated therefrom by a gate insulation layer 305. Adjacent the gate electrode, cavities 310, 311 comprising stress-creating elements 314, 315 may be formed. The stress-creating elements 314, 315 may comprise a material having a lattice constant different from that of the substrate 301. For example, in embodiments wherein the substrate 301 comprises silicon, the stress-creating elements 310, 311 may comprise a material having a lattice constant being greater than that of silicon, such as silicon germanide, to create a compressive stress in portions of the active region 304 below the gate electrode 306, or may comprise a material having a lattice constant smaller than that of silicon, such as silicon carbide, to create a tensile stress.

Similar to the first transistor element 330, the second transistor element 430 may comprise an active region 404, over which a gate electrode 406 and a gate insulation layer 405 are formed. Adjacent the gate electrode 406, cavities 410, 411 comprising stress-creating elements 414, 415 may be formed.

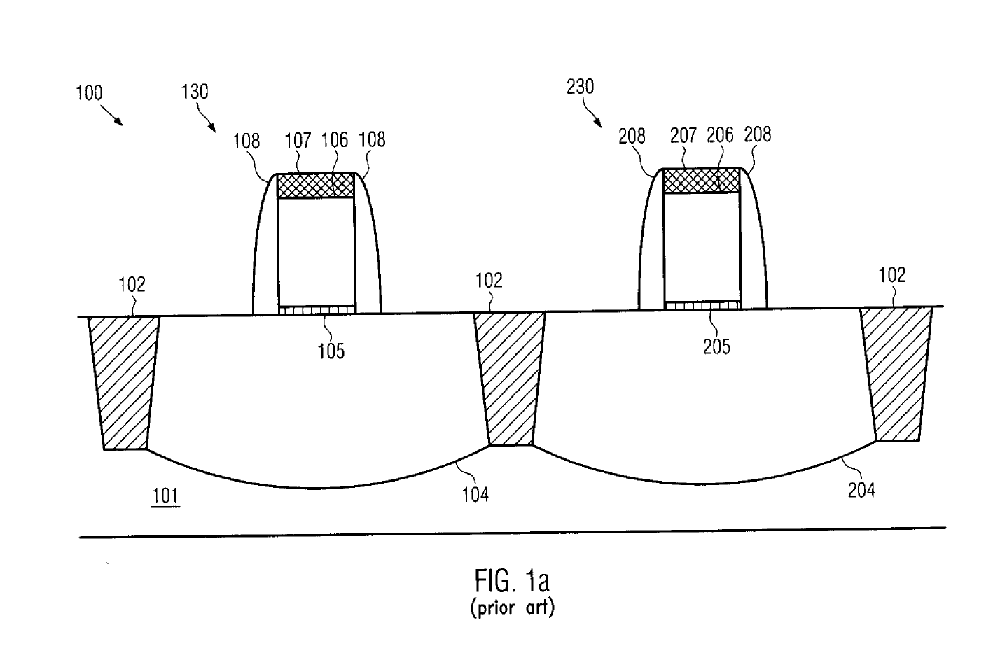

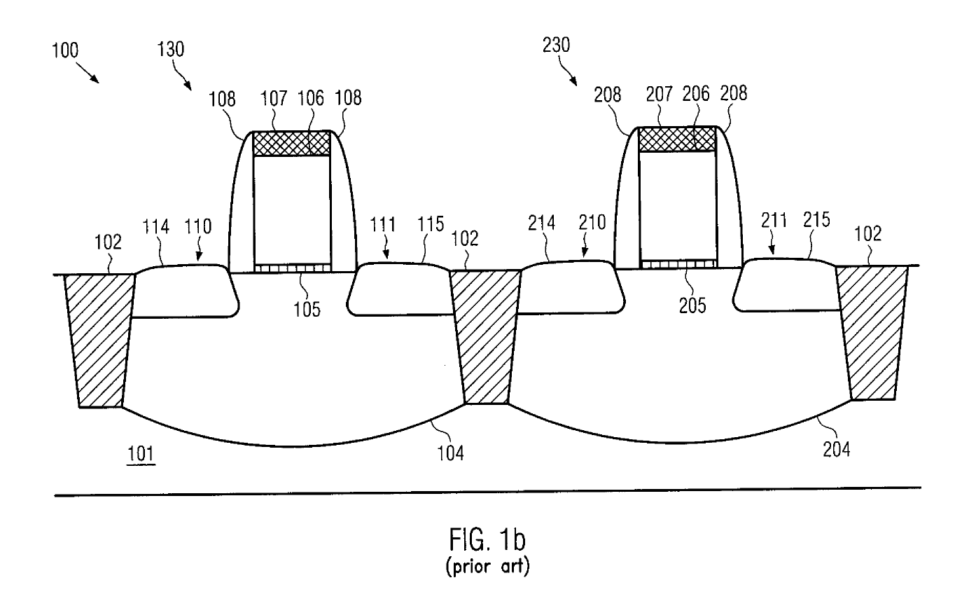

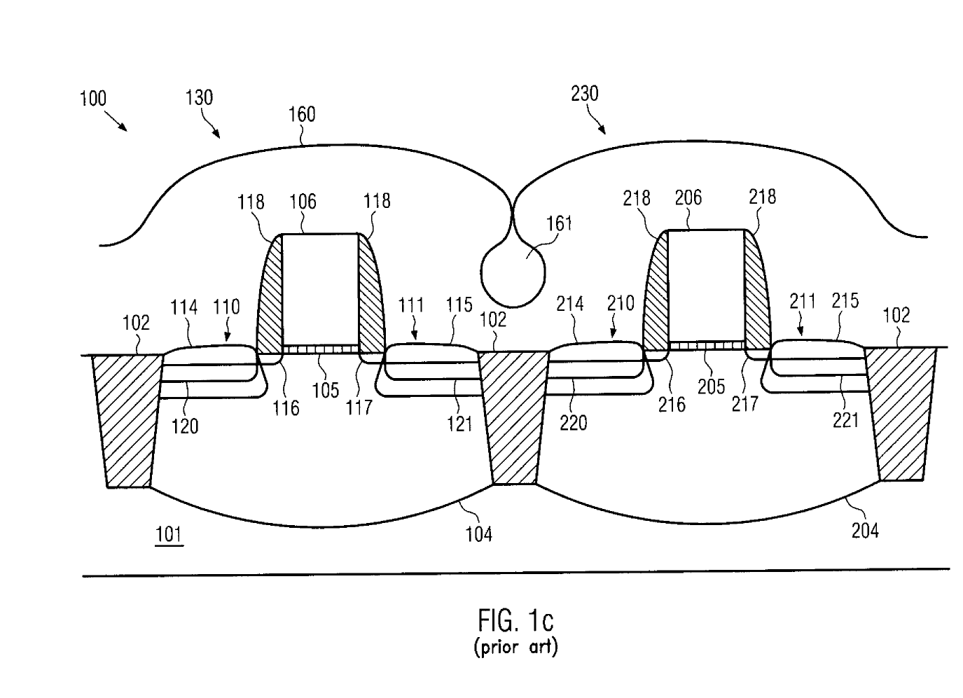

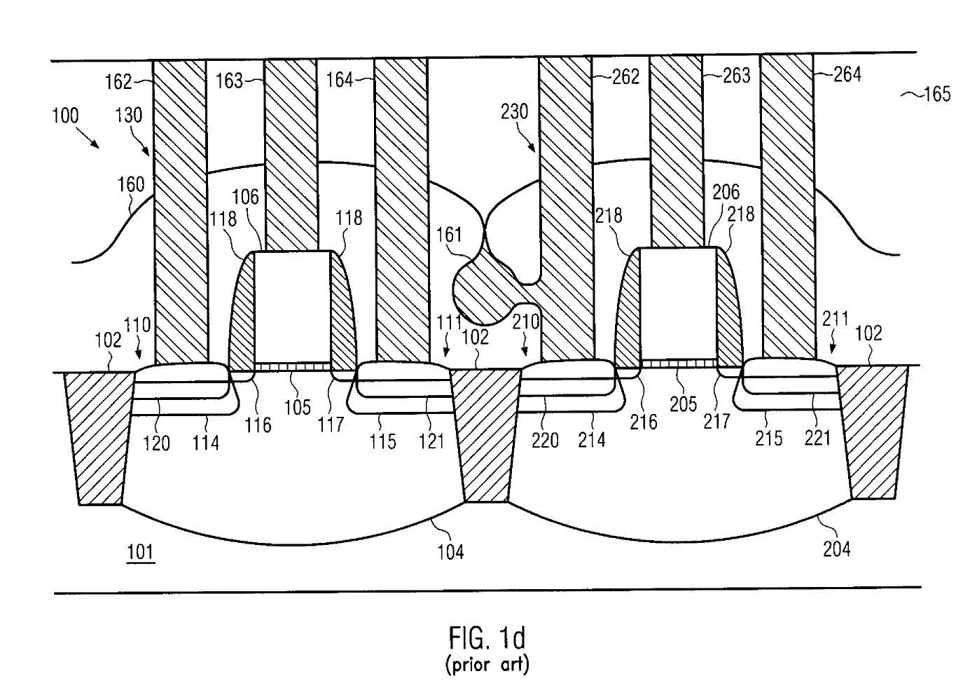

The above-described features may be formed by means of known techniques of photolithography, etching, oxidation, deposition, ion implantation and selective epitaxial growth similar to those described above with respect to FIG. 1a-1d. In the formation of the cavities 310, 311, 410, 411, in some embodiments, sidewall spacer structures similar to the sidewall spacer structures 108, 208 described above may be used, which may be removed after the formation of the cavities 310, 311, 410, 411. Thus, the cavities 310, 311 in the first transistor element 330 may be provided at a distance to the gate electrode 306, and the cavities 410, 411 may be provided at a distance to the gate electrode 406 of the second transistor element 430.

In portions of the substrate 301 adjacent the gate electrode 306 of the first transistor element 330, an inner extended source region 316 and an inner extended drain region 317 may be formed. Similarly, inner extended source and drain regions 416, 417 may be formed adjacent the gate electrode 406 of the second transistor element 430. To this end, the semiconductor structure 300 may be irradiated with ions of a dopant material. If the first transistor element 330 and the second transistor element 430 are N-type transistors, the semiconductor structure 300 may be irradiated with ions of an N-type dopant. Conversely, if the first transistor element 330 and the second transistor element 430 are P-type transistors, the semiconductor structure 300 may be irradiated with ions of a P-type dopant. If the first transistor element 330 and the second transistor element 430 are transistors of a different type, one of the transistor elements 330, 430 may be covered with a mask comprising, for example, a photoresist while ions are implanted into the other transistor element. In the ion implantation process, the gate electrodes 306, 406 absorb ions. Thus, no ions are implanted into portions of the substrate 301 below the gate electrodes 306, 406 wherein channel regions of the transistor elements 330, 430 are to be formed.

After the formation of the inner extended source regions 316, 416 and the inner extended drain regions 317, 417, a liner layer 380 and a material layer 370 may be formed over the semiconductor structure 300. The liner layer 380 and the material layer 370 may comprise dielectric materials which are chosen such that the materials of the liner layer 380 and the material layer 370 may be selectively etched. In one embodiment, the liner layer 380 may comprise one of silicon dioxide and silicon nitride, and the material layer 370 may comprise the other of silicon dioxide and silicon nitride. As is well known to persons skilled in the art, there are known etching processes adapted to remove silicon dioxide at a significantly greater etch rate than silicon nitride, and there are also known etching processes configured to remove silicon nitride at a significantly greater etch rate than silicon dioxide. Hence, in an etch process performed in order to etch the material layer 380 for forming a sidewall spacer structure 318 (FIG. 2b) from the material layer 380, which will be described in more detail below, the liner layer 380 may act as an etch stop layer protecting portions of the semiconductor structure 300 below the liner layer 380 from being affected by an etchant used in the etch process.

After the formation of the material layer 370, an ion implantation process may be performed. In the ion implantation process, the semiconductor structure may be irradiated with ions, as indicated schematically by arrows 390 in FIG. 2a. The ions may comprise ions of a noble gas. In one embodiment, the ions may comprise ions of xenon (Xe). A direction of incidence of the ions on the semiconductor structure 300 may be substantially perpendicular to a surface of the substrate 301.

The ions may penetrate the material layer 370. In the material layer 370, the ions collide with atoms of the material layer 370. In the collisions, momentum may be transferred from the ions to the atoms of the material layer 370. Therefore, the ions may be decelerated and, finally, stopped, while atoms of the material layer 370 may be knocked away from their positions in the material layer 370 at which they are chemically bound to neighboring atoms. Thus, the physical and/or chemical structure of the material layer 370 may be modified. The ions may penetrate the material layer 370 to a depth which may depend on the chemical species of the ions and the energy of the ions. In one embodiment, the semiconductor structure 300 may be irradiated with ions of xenon having an energy in a range from about 80-250 keV. An ion dose applied may have a value in a range from about 10¹⁵-5 10¹⁶ ions/cm².

A relatively high amount of ions may impinge on relatively weakly inclined portions of the layer 380 such as, for example, portions over the top surfaces of the gate electrodes 306, 406 and portions over the substrate 301. Hence, ion-implanted portions 372, 374 may be formed over the gate electrodes 306, 406, and further ion-implanted portions 371, 373, 375 may be formed over the substrate 301. In the ion-implanted portions 371-375, the structure of the material layer 370 may be modified physically and/or chemically due to the impact of the ions.

A less amount of ions, however, may impinge on substantially vertical portions of the material layer 370, such as, for example, portions 376, 377 over the sidewalls of the gate electrode 306 of the first transistor element 330 or portions 378, 379 over the sidewalls of the gate electrode 406 of the second transistor element 430. Since the ions may arrive from a direction of incidence substantially perpendicular to the surface of the substrate 301, and since the ions may penetrate the material layer 370 only to a limited depth smaller than a height of the gate electrodes 306, 406, only a relatively small amount of ions may reach the portions 376, 377, 378, 379 over the sidewalls of the gate electrodes 306, 406. Hence, the physical and/or chemical properties of the layer 370 may be modified in the portions 376, 377, 378, 379 only to a relatively small extent.

FIG. 2b shows a schematic cross-sectional view of the semiconductor structure 300 in a later stage of the manufacturing process. After performing the ion implantation process, an etching process may be performed to remove portions of the material layer 370 over the top surfaces of the gate electrodes 306, 406 and portions of the material layer 370 over the surface of the substrate 301 adjacent the gate electrodes 306, 406. The etching process may be a dry etching process which may be anisotropic. In anisotropic etching, an etch rate of portions of an etched material layer having a substantially horizontal surface parallel to the surface of the substrate 301 may be greater than an etch rate of portions of the material layer being inclined relative to the surface of the substrate 301.

As persons skilled in the art know, in dry etching, the semiconductor structure 300 is inserted into a reactor chamber. An etching gas may be supplied to the reaction chamber. In the etching gas, a glow discharge may be created by applying a radio-frequency alternating voltage between a pair of electrodes provided in the etching gas or by inductively coupling the radio-frequency alternating voltage to the etching gas. Due to the glow discharge, chemically reactive species such as ions and/or radicals may be created from the reaction gas. The chemically reactive species may react with the material layer 370, creating volatile compounds which may be pumped out of the reactor vessel. In addition to the radio-frequency alternating voltage, a bias voltage may be applied between the semiconductor structure 300 and the etching gas. The bias voltage, which may be a low frequency alternating voltage or a direct voltage, may accelerate ions towards the semiconductor structure 300. The direction of motion of the ions provides a directionality of the etching process, such that anisotropic etching may be obtained. In general, a higher bias voltage may lead to a greater anisotropy of the etching process. Parameters of the etching process, such as frequency and/or amplitude of the radio-frequency alternating voltage, as well as temperature, pressure and composition of the reaction gas for anisotropic etching of a material layer comprising dielectric materials such as silicon dioxide, silicon nitride and/or silicon oxynitride, are well known to persons skilled in the art and/or may be readily determined by routine experiments.

The etch rate obtained in the etch process may be further influenced by structural properties of the material layer 370. In particular, physical and/or chemical modifications of the material layer 370 in the ion-implanted portions 371-375 caused by the implantation of ions may lead to an increased etch rate of the ion-implanted portions compared to an etch rate of the material layer 370 which is obtained if the ion implantation process is omitted.

Since the ion-implanted portions 371-375 may be located in portions of the material layer 370 having a weakly inclined or substantially horizontal surface such as portions of the material layer 370 over the top surfaces of the gate electrodes 306, 406 or portions of the material layer 370 over the stress-creating regions 314, 315, 414, 415, the increase of the etch rate caused by the physical and/or chemical modifications originating from the ion implantation may enhance the effects of the anisotropy of the etch process. Thus, the etch rate of portions of the material layer 370 having a substantially horizontal or weakly inclined surface may be further increased.

The etch process may be stopped upon removal of portions of the material layer 370 having a substantially horizontal or weakly inclined surface such as the ion-implanted portions 371-375. Since the portions 376, 377, 378, 379 of the material layer 370 may have a smaller etch rate, these portions may remain, at least partially, on the surface of the semiconductor structure 300, and may form a sidewall spacer structure 318 adjacent the gate electrode 306 of the first transistor element 330, as well as a sidewall spacer structure 418 adjacent the gate electrode 406 of the second transistor element 430.

Since the etch rate of the material layer 370 in the ion-implanted portions 371-375 has been increased by the physical and/or chemical modifications caused by the impact of the ions, the etch time required to remove the ion-implanted portions 371-375 may be reduced such that, in the portions 376, 377, 378, 379 of the material layer 370, a smaller amount of material may be removed during the etch process compared to an embodiment wherein the ion implantation process is omitted.

A thickness of the sidewall spacer structures 318, 418 obtained after the etch process may be influenced by variations of the deposition process used to form the material layer 370 and by variations of the etch process used to remove the ion-implanted portions 371-375. In some embodiments, the variations introduced by the deposition process may be smaller than the variations introduced by the etch process, since known deposition processes may have better controllability than known etch processes. Since the formation of the ion-implanted portions 371-375 may reduce an amount of material removed in the etch process, the shape of the sidewall spacer structures 318, 418 may be influenced to a less extent by the variations of the etch process. Therefore, the sidewall spacer structures 318, 319 may be formed more precisely than in embodiments wherein the ion-implantation process is omitted. Additionally, the sidewall spacer structures 318, 418 may be steeper.

After the formation of the sidewall spacer structures 318, 418, an ion implantation process may be performed wherein the semiconductor structure 300 is irradiated with ions of a dopant material to form outer extended source regions 319, 419 and outer extended drain regions 320, 420 adjacent the gate electrodes 306, 307. In embodiments wherein the first transistor element 330 and the second transistor element 430 are transistors of a different type, two ion implantation processes may be performed, wherein the transistor elements 330, 430 may be successively covered by masks while ions are implanted into the respective other of the transistor elements 330, 430. Since the sidewall spacer structures 318, 418 may absorb ions impinging on the sidewall spacer structures 318, 418, the outer extended source regions 319, 419 and the outer extended drain regions 320, 420 may be provided at a greater distance to the gate electrodes 306, 406 than the inner extended source regions 316, 416 and the inner extended drain regions 317, 417. Moreover, the outer extended source regions 319, 419 and the outer extended drain regions 320, 420 may have a different depth, for example, a greater depth, which may be achieved by providing a greater energy of the ions.

Subsequently, a liner layer 381 and a material layer 382 may be deposited over the semiconductor structure 300. The liner layer 381 and the material layer 382 may comprise different dielectric materials adapted such that the material layer 382 and the liner layer 381 may be etched selectively. In some embodiments, the liner layer 381 may comprise substantially the same material as the liner layer 380, and the material layer 382 may comprise substantially the same material as the material layer 370.

FIG. 2c shows a schematic cross-sectional view of the semiconductor structure 300 in a later stage of the manufacturing process. After the formation of the material layer 382, a further etching process may be performed to form sidewall spacer structures 383, 483 adjacent the gate electrodes 306, 406 of the first transistor element 330 and the second transistor element 430.

The etch process employed in the formation of the sidewall spacer structures 383, 483 may be an anisotropic dry etch process, similar to the etch process used in the formation of the sidewall spacer structures 318, 418. The etch process may remove portions of the material layer 382 over the top surfaces of the gate electrodes 306, 406, the stress-creating elements 314, 315, 414, 415 and the trench isolation structure 302, while portions of the material layer 382 over the side surfaces of the gate electrodes 306, 406 may at least partially remain on the substrate 301 to form the sidewall spacer structures 383, 483.

In some embodiments, an ion implantation process may be performed before the material layer 382 is etched, similar to the ion implantation process used in the formation of the sidewall spacer structures 318, 418. In the ion implantation process, ions of a noble gas such as xenon may be implanted into the semiconductor structure 300. Thus, ion-implanted portions (not shown) may be formed in the material layer 382. A direction of incidence of the ions may be substantially perpendicular to the surface of the substrate 301, such that the ion-implanted portions are located over the top surfaces of the gate electrodes 306, 406 and over portions of the substrate 301 adjacent the gate electrodes 306, 406. A significantly lower amount of ions, however, may impinge on portions of the material layer 382 over the sidewalls of the gate electrodes 306, 406 such that substantially no ion-implanted portions are formed over the sidewalls of the gate electrodes 306, 406. When the material layer is etched, an etch rate of the ion-implanted portions may be greater than an etch rate of portions of the material layer 382 over the side surfaces of the gate electrodes 306, 406. Thus, the anisotropy of the etch process may be enhanced. In some embodiments, this may help to obtain a more tapered profile of the sidewall spacer structures 383, 483.

After the formation of the sidewall spacer structures 383, 483, an ion implantation process wherein ions of a dopant material are implanted into the semiconductor structure 300 may be performed to form source regions 321, 421 and drain regions 322, 422 adjacent the gate electrodes 306, 406. The sidewall spacer structures 383, 483, as well as the sidewall spacer structures 318, 418, may absorb ions impinging thereon. Therefore, the source regions 321, 322, 421, 422 may be spaced apart from the gate electrodes 306, 406 by a distance corresponding to the thickness of the sidewall spacer structures 318, 383, 418, 483 and being greater than a distance between the gate electrodes 306, 406 and the inner extended source and drain regions 316, 317, 416, 417 or the outer extended source and drain regions 319, 320, 419, 420, respectively. Moreover, an energy of the dopant ions may be greater than an ion energy applied in the formation of the inner extended source and drain regions 316, 317, 416, 417 and the outer extended source and drain regions 319, 320, 419, 420.

After the formation of the source regions 321, 421 and the drain regions 322, 422, an ion implantation process may be performed to form ion-implanted portions 384, 484 in the sidewall spacer structures 383, 483. Similar to the formation of the ion-implanted portions 371-379 in the material layer 370 described above, the semiconductor structure 300 may be irradiated with ions, for example, ions of a noble gas such as xenon. In FIG. 2c, the irradiation of the semiconductor structure 300 with the ions is indicated schematically by arrows 391. An energy of the ions may be adapted such that the ions may penetrate the sidewall spacer structures 383, 483 to a depth being smaller than the height of the gate electrodes 306, 406. In one embodiment, the ions have an energy in a range from about 80-250 keV. An ion dose may be adapted such that the chemical structure of the material of the sidewall spacer structures 383, 483 is modified in the ion-implanted portions 384, 484. In one embodiment, the ion dose may have a value in a range from about 10¹⁵-5 10¹⁶ ions/cm².

A direction of incidence of the ions may be substantially perpendicular to the surface of the substrate 301. Therefore, a relatively large amount of ions may impinge at the top of the sidewall spacer structures 383, 483, whereas a relatively small amount of ions impinges at the bottom of the sidewall spacer structures 383, 483. Hence, the ion-implanted portions 384, 484, wherein the physical and/or chemical structure of the material of the sidewall spacer structures 318, 418 is modified, are formed at the top of the sidewall spacer structures 318, 418, whereas the physical and/or chemical structure of the material of the sidewall spacer structures 383, 483 may remain substantially unmodified or may be modified only to a lower extent at the bottom of the sidewall spacer structures 383, 483.

In addition to the ion-implanted portions 384, 484 formed in the sidewall spacer structures 383, 483, further ion-implanted portions 385, 386, 387, 388, 389 may be formed in the liner layers 380, 381 during the ion implantation process. The ion-implanted portions 385, 386, 387 are located over the stress-creating regions 314, 315, 414, 415 and the trench isolation structure 302. The ion-implanted portions 388, 389 are located over the top surfaces of the gate electrodes 306, 406.

After the formation of the ion-implanted portions 385-389, 384, 484, an etching process adapted to remove the ion-implanted portions 384, 484 at a greater etch rate than other portions of the sidewall spacer structures 383, 483, such as, for example, portions of the sidewall spacers structures 383, 483 at the bottom of the sidewall spacer structures 383, 483, and to remove the ion-implanted portions 385-389 in the liner layers 380, 381 at a greater etch rate than the liner layers 380, 381 when not irradiated with ions, may be performed.

In some embodiments, the etch process may comprise a wet etch process wherein the semiconductor structure 300 is exposed to an etchant which is adapted to remove the material of the liner layers 380, 381, and which is further adapted to affect the material of the sidewall spacers structures 318, 383. In some of these embodiments, the wet etchant may comprise hydrofluoric acid (HF). In other embodiments, a dry etch process may be used.

Since the physical and/or chemical structure of the material of the sidewall spacer structures 383, 483 has been modified in the ion implantation process, the ion-irradiated portions 384, 484 may be affected by the etchant to a greater extent than other portions of the sidewall spacer structures 383, 483. Therefore, a thickness of the sidewall spacer structures 383, 484 may be reduced in the vicinity of the top surfaces of the gate electrodes 306, 406, whereas the thickness of the sidewall spacer structures 383, 483 in the vicinity of the bottom of the sidewall structures 383, 483 may be reduced to a less extent. Thus, the sidewall spacer structures 383, 384 may obtain a tapered shape, as shown schematically in FIG. 2d.

Since the chemical structure of the liner layers 380, 381 in the ion-irradiated portions 385-389 has been modified by the ion irradiation process, the liner layers 380, 381 may be more efficiently removed from the semiconductor structure 300 than in embodiments wherein the ion irradiation process is omitted.

FIG. 2d shows a schematic cross-sectional view of the semiconductor structure 300 in a later stage of the manufacturing process. After the etch process, a layer 360 of a dielectric material may be formed over the semiconductor structure 300. The layer 360 may, for example, comprise silicon nitride, and may be formed by means of deposition techniques well known to persons skilled in the art, such as chemical vapor deposition and/or plasma enhanced chemical vapor deposition. Parameters of the deposition process may be adapted such that the layer 360 is subject to a compressive stress. In other examples, the layer 360 may be subject to a tensile stress. Thus, the stress exerted by the stress-creating regions 314, 315, 414, 415 to portions of the substrate 301 below the gate electrodes 306, 406 may be modified. In embodiments wherein the stress-creating regions 314, 315, 414, 415 are adapted to exert a compressive stress to portions of the substrate 301 below the gate electrodes 306, 406, a compressive intrinsic stress of the layer 360 may enhance the stress in the substrate portions, whereas a tensile intrinsic stress of the layer 360 may reduce the stress in the substrate portions. Conversely, in embodiments wherein the stress-creating regions 314, 315, 414, 415 are adapted to exert a tensile stress to the substrate portions, the tensile stress may be reduced by providing the layer 360 with a compressive intrinsic stress, and may be enhanced by providing the layer 360 with a tensile intrinsic stress.

In further embodiments, the layer 360 may comprise a portion comprising one of a compressive intrinsic stress and a tensile intrinsic stress which is provided over the first transistor element 330 and a portion comprising the other of a compressive intrinsic stress and a tensile intrinsic stress provided over the second transistor element 430. In such embodiments, the portions of the layer 360 may be formed sequentially. First, a compressively stressed layer of the dielectric material may be formed over the semiconductor structure 300. Thereafter, a portion of the compressively stressed layer over one of the transistor elements 330, 430 may be removed by means of known methods of photolithography and etching. Subsequently, a tensile stressed layer of the dielectric material may be deposited over the semiconductor structure 300, and a portion of the tensile stressed layer over the other of the transistor elements 330, 430 may be removed by means of photolithography and etching.

Since, as detailed above, the sidewall spacer structures 383, 483 have obtained a tapered configuration in the etch process performed after the creation of the ion-implanted portions 384, 484, the space between the gate electrodes 306, 406 may have a shape similar to that of a groove having sloped walls. Therefore, in the deposition process performed in the formation of the layer 360, reactant gases may more efficiently enter the space between the gate electrodes 306, 406 than in the method according to the state of the art described above with reference to FIGS. 1a-1d. Thus, an undesirable formation of voids between the gate electrodes 306, 406 may be advantageously avoided.

After the formation of the layer 306, a further layer 365 of a dielectric material may be deposited over the semiconductor structure 300, and contact vias 362, 363, 364 may be formed and filled with an electrically conductive material, such as tungsten, to provide electrical connections to the source region 321, the gate electrode 306 and the drain region 322 of the first transistor element 330. Similarly, contact vias 462, 463, 463 filled with electrically conductive material may be formed to provide electrical connections to the source region 421, the gate electrode 406 and the drain region 422 of the second transistor element 430. This may be done by means of known methods of photolithography, etching and deposition. Additionally, the layer 365 may be planarized, for example, by means of a known chemical mechanical polishing process.

The present disclosure is not restricted to embodiments wherein ion-implanted regions are formed in each of the material layers 370, 382 and in the liner layers 380, 381. Moreover, ion-implanted regions need not be formed in the material layer 382 both before the formation of the sidewall spacer structures 383, 483 and after the formation of the sidewall spacer structures 383, 483. In other embodiments, one or more of the ion implantation processes performed to create ion-implanted portions of the material layers 370, 382 described above may be omitted. Moreover, the present disclosure is not restricted to embodiments wherein two sidewall spacer structures are formed adjacent each of the gate electrodes 306, 406. In other embodiments, only one sidewall spacer structure may be formed adjacent each of the gate electrodes 306, 406, similar to the method according to the state of the art described above with reference to FIGS. 1a-1d. In still further embodiments, three or more sidewall spacer structures may be formed adjacent each of the gate electrodes 306, 406.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor structure, comprising:
providing a semiconductor substrate, a feature being formed over said substrate, said feature having a side surface and a top surface;
forming a material layer over said substrate, said material layer covering at least said side surface of said feature;
performing an ion implantation process to create an ion-implanted portion in said material layer; and
performing a first etch process adapted to remove said ion-implanted portion in said material layer at a greater etch rate than other portions of said material layer.

2. The method of claim 1, wherein said formation of said material layer comprises:
depositing said material layer over said substrate; and
performing an anisotropic second etch process to remove portions of said material layer over said top surface of said feature.

3. The method of claim 2, wherein said feature comprises a gate electrode, and wherein said second etch process is adapted such that a portion of said material layer remains over said side surface to form a sidewall spacer structure adjacent said gate electrode.

4. The method of claim 1, wherein said material layer is provided over said top surface and said side surface, and wherein said ion-implanted portion is formed over said top surface.

5. The method of claim 4, wherein a portion of said material layer over said top surface is removed by said etch process.

6. The method of claim 5, wherein said feature comprises a gate electrode, and wherein said first etch process is adapted such that a portion of said material layer remains over said side surface to form a sidewall spacer structure.

7. The method of claim 1, wherein said first etch process comprises a wet etch process.

8. The method of claim 1, wherein said first etch process comprises a dry etch process.

9. The method of claim 8, wherein said first etch process is anisotropic.

10. A method of forming a semiconductor structure, comprising:
providing a semiconductor substrate, a gate electrode being formed over said substrate, said gate electrode having a top surface and a side surface;
depositing a first material layer over said top surface and said side surface;
performing a first ion implantation process to create a first ion-implanted portion in said material layer over said top surface of said gate electrode; and
performing a first etch process adapted to remove said first ion-implanted portion at a greater etch rate than other portions of said first material layer, said etch process being stopped upon a removal of a portion of said first material layer over said top surface such that portions of said first material layer over said side surface form a first sidewall spacer structure adjacent said gate electrode.

11. The method of claim 10, further comprising forming a second sidewall spacer structure adjacent said first sidewall spacer structure.

12. The method of claim 11, wherein said formation of said second sidewall spacer structure comprises:
depositing a second material layer over said top surface and said side surface;
performing a second ion implantation process to create a second ion-implanted portion in said second material layer over said top surface; and
performing a second etch process adapted to remove said second ion-implanted portion at a greater etch rate than other portions of said second material layer, said second etch process being stopped prior to complete removal of said second material layer.

13. The method of claim 11, further comprising:
performing a second ion implantation process to create a second ion-implanted portion in said second sidewall spacer structure; and
performing a second etch process adapted to remove said second ion-implanted portion at a greater etch rate than other portions of said second sidewall spacer structure.

14. The method of claim 10, wherein a direction of incidence of ions in said ion implantation process is substantially perpendicular to said top surface.

15. The method of claim 10, further comprising depositing a layer of a dielectric material over said substrate.

16. The method of claim 14, wherein said layer of dielectric material comprises an intrinsic stress.

17. A method of forming a semiconductor structure, comprising:
providing a semiconductor substrate comprising a gate electrode and a sidewall spacer structure formed adjacent said gate electrode;
performing an ion implantation process to form an ion-implanted portion in said sidewall spacer structure; and
performing an etch process adapted to remove said ion-implanted portion at a greater etch rate than other portions of said sidewall spacer structure, said etch process being stopped prior to complete removal of said sidewall spacer structure.

18. The method of claim 17, wherein said etch process comprises a wet etch process.

19. The method of claim 17, wherein a direction of incidence of ions in said ion implantation process is substantially perpendicular to a top surface of said gate electrode.

20. The method of claim 17, further comprising forming a layer of a dielectric material comprising an intrinsic stress over said substrate.
